(19) United States
(12) Patent Application Publication
(10) Pub. No.: US 2013/0043544 A1
(43) Pub. Date: Feb. 21, 2013

(54) STRUCTURE HAVING THREE INDEPENDENT FINFET TRANSISTORS

(71) Applicants: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US); Kelly L. Williams, Rochester, MN (US)

(72) Inventors: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US); Kelly L. Williams, Rochester, MN (US)

(73) Assignee: INTERNATIONAL BUSINESS MACHINES CORPORATION, Armonk, NY (US)

(21) Appl. No.: 13/211,445

(22) Filed: Aug. 17, 2011

(51) Int. Cl. H01L 27/088; H01L 21/8234

(52) U.S. Cl. 257/401; 438/279; 257/E27.06; 257/E21.62

(57) ABSTRACT

A semiconductor chip has a FinFET structure with three independently controllable FETs on a single fin. The three FETs are connected in parallel so that current will flow between a common source and a common drain if one or more of the three independently controllable FETs is turned on. The three independently controllable FETs may be used in logic gates.

### FIELD OF THE INVENTION

This invention relates generally to semiconductor chips, and more specifically to a structure having three independent FinFET transistors on a single fin.

### SUMMARY OF THE EMBODIMENTS OF THE INVENTION

A semiconductor chip used in an electronic system is an expensive component in the electronic system. Therefore, chip designers try to maximize circuit density on the semiconductor chip.

FinFETs are known in the art as a design and processing technique to provide further density improvements. A “fin” of semiconductor material extends upwards from a substrate and further processing creates a gate dielectric (typically SiO2, HfO2, or similar dielectric) and a gate electrode on two vertical sides and a top of the fin. Source/drain implanting suitably dopes the fin except a portion of the fin covered by the gate oxide and gate electrode, leaving that portion having an original doping of the fin which is suitable for a body of a field effect transistor (FET). Many logic structures such as NANDs and NORs require three parallel connected FETs. For example, a CMOS three way NAND circuit uses three PFETs (P channel Field Effect Transistors) connected in parallel between a supply voltage and an output node. A CMOS three way NOR circuit uses three NFETs (N channel field effect transistors) connected in parallel between ground and an output node.

Taught herein is a FinFET structure that provides three independently controllable FETs on a single fin. The three FETs are connected in parallel between a common source and a common drain.

A first of the three FETs is on a first vertical side of the fin. A second of the three FETs is on a top surface of the fin. A third of the three FETs are on a second vertical surface of the fin.

Also taught herein is a method of creating three independently controllable, parallel-connected FETs on a single fin. The method comprises creating, on a top surface of a semiconductor substrate, a fin of suitable doping for a body of a FET. A first thin dielectric layer, suitable as a gate dielectric, is deposited or grown on a top surface of the semiconductor substrate and the fin. A first gate electrode layer, such as doped polysilicon, is deposited or grown over the first thin dielectric layer. Etching of the first gate dielectric layer and the first gate electrode layer is then performed to define a conventional gate dielectric and gate electrode structure commonly used on FinFETs. Source/drain areas are implanted, using the gate dielectric and gate electrode as a mask. Planarization (or, alternatively, a series of etching steps) is then done, deeply enough to remove a top portion of the fin and an overlying portion of the first gate dielectric layer and the first gate electrode layer. At this time, remaining portions of the first gate dielectric layer and the first gate electrode layer remain on vertical surfaces of the fin. A second thin dielectric layer and a second gate electrode layer are deposited and then etched such that a remaining portion of the second thin dielectric layer electrically isolates a remaining portion of the second gate electrode layer from the two remaining portions of the first gate electrode layer on the vertical sides of the fin.

A first FET comprises the remaining portions of the first gate dielectric and the gate electrode on a first vertical side of the fin. A second FET comprises the remaining portions of the second gate dielectric layer and the second gate electrode layer on a top surface of the fin. A third FET comprises the remaining ports of the first gate dielectric layer and the first gate electrode layer on a second vertical side of the fin. Source and drain for the three FETs are portions of the fin extending beyond the gate areas, as is common in FinFET technology.

### BRIEF DESCRIPTION OF THE DRAWINGS

FIG. 1 shows a cross sectional view through a FinFET structure.

FIG. 2 shows the cross sectional view of FIG. 1 after a planarization process.

FIG. 3 shows the cross sectional view of FIG. 2 after growth or deposition of a gate dielectric layer and a polysilicon layer.

FIG. 4 shows the cross sectional view of FIG. 3 after selective removal of portions of the gate dielectric layer and the polysilicon layer.

FIG. 5 shows the cross sectional view of FIG. 4 after growth of additional oxide.

FIG. 6 shows the cross sectional view of FIG. 5 after addition of electrical contacts.

FIG. 7 shows a three dimensional view of FIG. 6 at a cross section through the FinFET structure. Three independently controllable FET devices are schematically depicted.

FIG. 8 shows a three dimensional view of a completed FinFET having three independently controllable parallel connected FET devices.

FIG. 9 shows the apparatus of FIG. 1 after a timed oxide etch.

FIG. 10 shows the apparatus of FIG. 9 after a selective polysilicon etch.

FIG. 11 shows the apparatus of FIG. 10 after a selective oxide etch.

FIG. 12 shows the apparatus of FIG. 11 after growth of a thin dielectric layer and growth/deposition of a polysilicon layer.

FIG. 13 shows a schematic of a 3-way CMOS NOR gate. The three NFETs in the CMOS NOR gate being the three NFETs shown in FIG. 7.

### DETAILED DESCRIPTION OF THE EMBODIMENTS

In the following detailed description of embodiments of the invention, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

A semiconductor chip used in an electronic system is an expensive component in the electronic system. Therefore, chip designers try to maximize circuit density on the semiconductor chip.

FinFETs are known in the art as a design and processing technique to provide further density improvements. A “fin” of semiconductor material extends upwards from a substrate and further processing creates a gate dielectric layer (e.g., SiO2 or HfO2, etc) and a gate electrode layer on two vertical sides and a top of the fin. Source/drain implanting suitably dopes the fin except a portion of the fin covered by the gate oxide and gate electrode, leaving that portion having an original doping of the fin which is suitable for a body of a field effect transistor (FET).

Currently disclosed is an apparatus comprising three independently controlled FETs connected in parallel on a single fin. This apparatus is useful for parallel NFETS (N channel Field Effect Transistors) such as are used in a NOR logic gate, or for parallel PFETS (P Channel Field Effect Transistors) in a NAND logic gate.

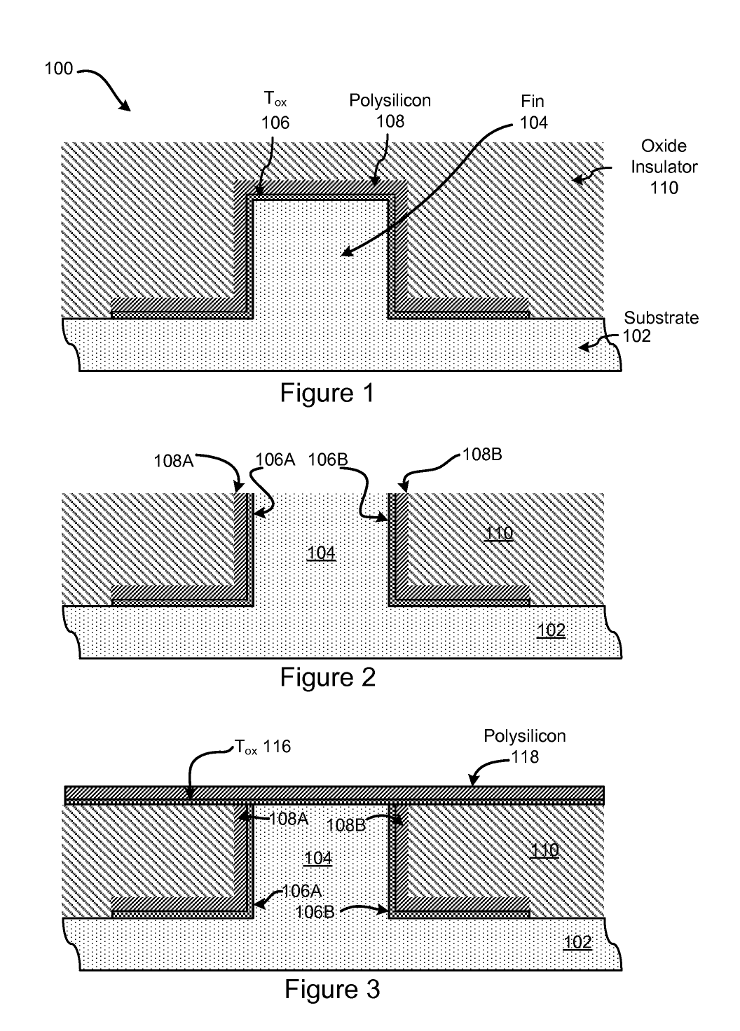

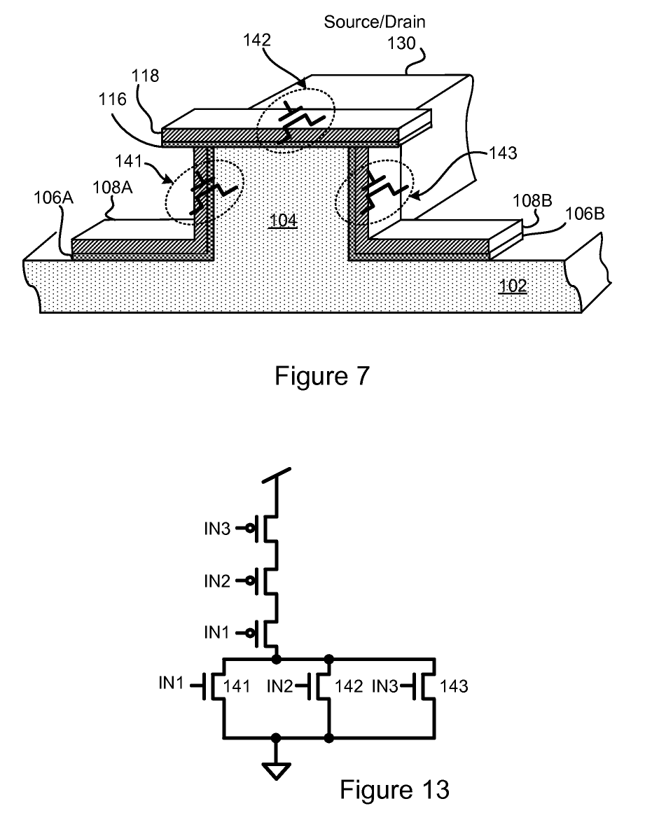

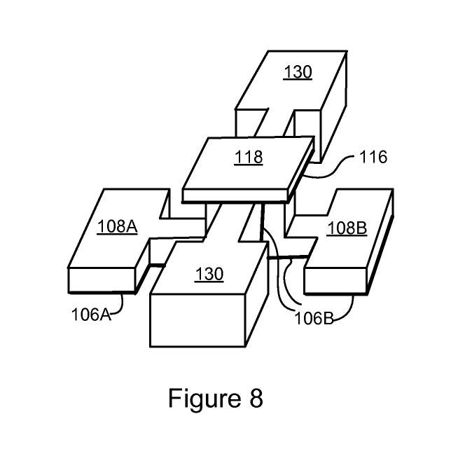

Having reference now to FIGS. 1-6 and 9-12, which represent a cross sectional view through an area of the fin which forms a body of the three FETs, a process of creating the three FETs is shown. FIGS. 7 and 8 show three dimensional views of the structure.

In FIG. 1, semiconductor chip 100 is shown; processing has created a fin 104 on a substrate 102. A first thin oxide layer, thin oxide 106, has been deposited on fin 104 as shown. Thin oxide 106 may be any dielectric suitable as a gate dielectric of a FET, for examples, SiO2 or HfO2. A first polysilicon layer, polysilicon 108, is deposited over the thin oxide 106. Polysilicon 108 is suitable as a gate electrode material and is suitably doped as a conductor. Polysilicon 108 may be silicided (e.g., titanium silicide) to enhance conductivity. Polysilicon layer 108 may generically also be referred to as a gate electrode layer. An oxide insulator 110 is deposited to cover fin 104, substrate 102, thin oxide 106, and polysilicon 108. Fin 104 is a silicon structure that rises from substrate 102 and has a doping suitable for a body of an FET (e.g., P− doping, in the case of an NFET). After deposition and selective etching of thin oxide 106 and polysilicon 108, an ion implant is done, using the remaining portions of thin oxide 106 and polysilicon 108 as a mask, to change the doping of exposed portions of fin 104 to be suitable (e.g., N+ doping, in the case of an NFET) for source/drain regions of the FETs herein disclosed.

FIG. 2 shows the apparatus of FIG. 1 after planarization (e.g., chemical-mechanical polishing (CMP)). The CMP has removed a top portion of fin 104 and portions of thin oxide 106 and polysilicon 108 as shown. At this point, thin oxide 106 is no longer a contiguous piece of thin oxide, and isolated portions are denoted as thin oxide 106A (left portion) and thin oxide 106B (right portion). Likewise, polysilicon 108 is no longer contiguous and isolated portions of polysilicon 108 are denoted as polysilicon 108A (left portion) and polysilicon 1088 (right portion).

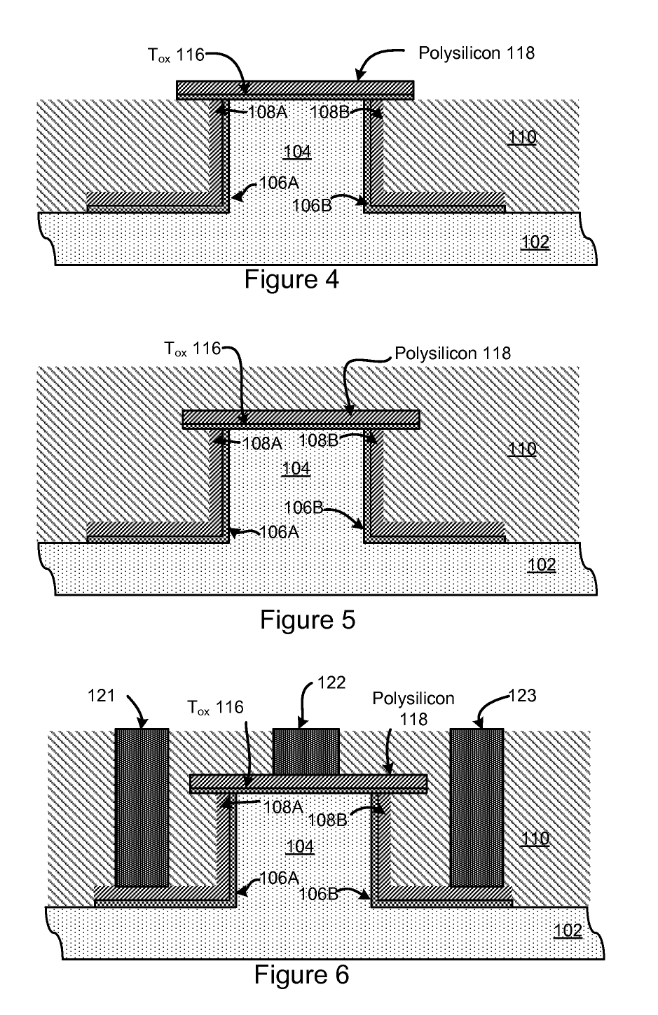

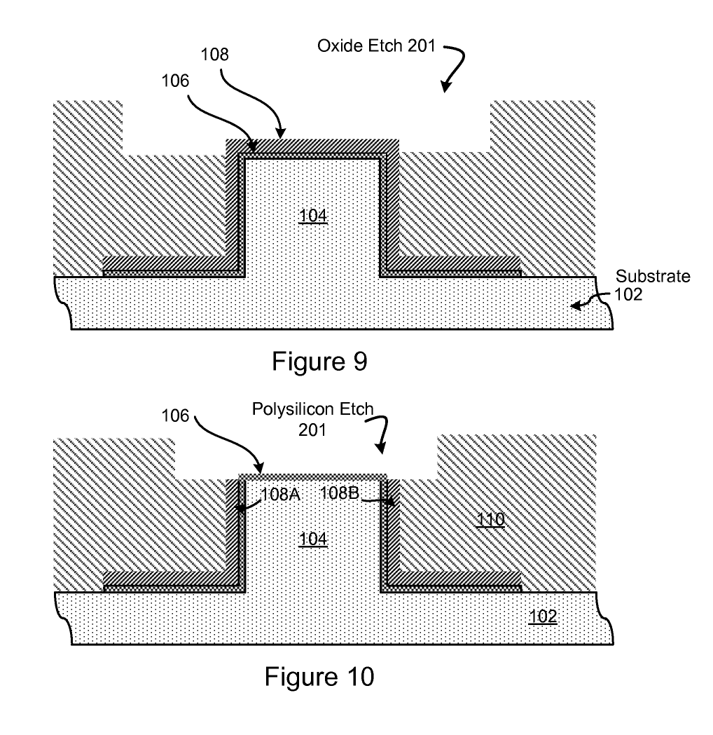

FIG. 9 shows a first processing step that is an alternative to the CMP step described in FIG. 2, and in processing steps shown in FIGS. 3 and 4.

In FIG. 9, a timed oxide etch 201 removes a portion of oxide insulator 110 as depicted. Polysilicon 108 and thin oxide 106 remain on a top surface of fin 104.

FIG. 10 shows a selective polysilicon etch to remove the portion of polysilicon 108 that is on the top surface of fin 104. Polysilicon 108 is no longer contiguous, and, as in FIG. 2, the remaining portions of polysilicon 108 are referenced as polysilicon 108A (left portion) and polysilicon 108B (right portion). Thin oxide 106, in FIG. 10, remains contiguous.

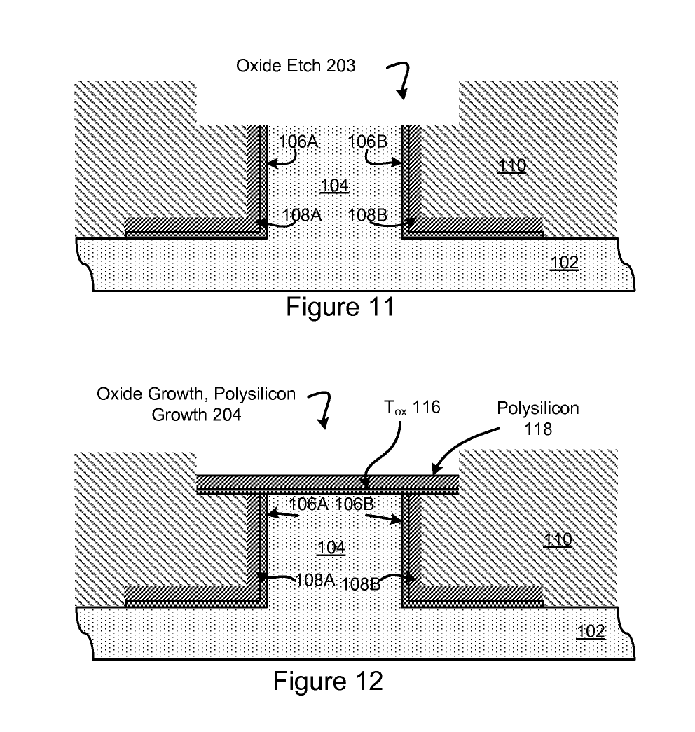

FIG. 11 shows the apparatus of FIG. 10 after a selective oxide etch to remove the portion of oxide 106 that remained on the top surface of fin 104, thereby leaving thin oxide portions 106A (left portion) and 106B (right portion) as shown.

FIG. 12 shows the apparatus of FIG. 11 after formation of thin oxide 116 (e.g., SiO2 or HfO2) and polysilicon 118. Note that thin oxide 116 overlaps top portions of polysilicon 108A and 1088 to electrically isolate polysilicon 118 from polysilicon 108A and 1088. At the end of the processing shown in FIG. 12, the apparatus is in a similar form as shown in FIG. 4. Then, oxide growth thickens oxide insulator 110 as shown in FIG. 5.

FIG. 3 shows the apparatus of FIG. 2 after deposition or growth of a second thin oxide layer, thin oxide 116, and a second polysilicon layer, polysilicon 118. As with thin oxide 106, thin oxide 116 may be any dielectric suitable as a gate dielectric for a FET, such as, but not limited to SiO2 or HfO2. Polysilicon 118 is suitably doped to serve as a gate electrode and, similar to polysilicon 108, may be silicided to increase conductivity.

FIG. 4 shows the apparatus of FIG. 3 after removal (e.g., by etching) of polysilicon 118 and thin oxide 116) as depicted. Note that a remaining portion of thin oxide 116 extends beyond polysilicon 108A and polysilicon 1088 and therefore electrically isolates a remaining portion of polysilicon 118 from polysilicon 108A and polysilicon 108B.

FIG. 5 shows the apparatus of FIG. 4 after growth of additional oxide, shown for simplicity as an increased thickness of oxide insulator 110.

FIG. 6 shows addition of contacts to polysilicon 108A, 1088, and 118. Contact 121 contacts polysilicon 108A; polysilicon 108A is a gate electrode of a first FET. Contact 122 contacts polysilicon 118; polysilicon 118 is a gate electrode of a second FET. Contact 123 contacts polysilicon 1088; polysilicon 1088 is a gate electrode of a third FET. Gate oxides 106A, 116, and 1068 are, respectively, gate dielectrics of the first, second, and third FETs. Generally, contacts must be wider than a length of an FET; therefore, polysilicon 108A, polysilicon 118, and polysilicon 1088 must be large enough for contact(s) to be reliably made in a given semiconductor technology, as best shown in FIG. 8.

FIG. 7 shows a three dimensional view of the apparatus, with oxide insulator 110 omitted for clarity. A first source/drain 130 is shown. A second source/drain 130 is not visible in FIG. 7 because FIG. 7 is cross sectioned through the fin in a region of the fin where the FETs are formed. The second source/drain region 130 is shown in FIG. 8. The first, second, and third FETs are shown schematically as FETs 141, 142, and 143.

FET 141 is on a first vertical surface of the fin. FET 142 is on a top surface of the fin; FET 143 is on a second vertical surface of the fin.

FETs 141, 142, and 143 are shown angled to ensure clarity that current flow is from (or to) the source/drain 130 depicted in FIG. 7 to (or from) the second source/drain 130 shown in FIG. 8.

As explained above, FETs 141, 142, and 143 are connected in parallel and are independently controllable because gate electrodes 108A, 118, and 1088 are not electrically connected to each other. Assuming NFETs (rather than PFETs, which are also contemplated), if polysilicon 108A which is the gate electrode for FET 141 is at a “high” voltage (i.e., above a threshold for FET 141), a channel is formed in fin 104 and current may flow between the two source/drain 130 regions (both shown in FIG. 8). Similarly, if polysilicon 118 which is the gate electrode of FET 142 is “high”, then FET 142 will allow current to flow between the two source/drain 130 regions. And, if polysilicon 1088 which is the gate electrode of FET 143 is “high”, then FET 143 will allow current to flow between the two source/drain 130 regions. If polysilicon 108A, polysilicon 118, and polysilicon 1088 are all “low” (below FET threshold) then FETs 141, 142, and 143 are all turned off, and no current (except very small subthreshold currents and leakage currents known in the art) will flow between the two source/drain 130 regions.

FIG. 13 shows an exemplary use of FETs 141, 142, and 143 (NFETs shown) used in a logic circuit, a three way NOR. PFET embodiments of FETs 141, 142, and 143 may be used in a three way NAND.

FIG. 8 shows a three dimensional view of the apparatus, with oxide insulator 110 omitted for clarity. As shown, contacts 121, 122, and 123 (FIG. 6) may be made to polysilicon 108A which is the gate electrode for FET 141, polysilicon 118 which is the gate electrode for FET 142, and polysilicon 1088 which is the gate electrode for FET 143, where FETs 141, 142, and 143 are shown schematically in FIG. 7.

What is claimed is:

1. A semiconductor chip comprising a FinFET structure comprising:
Three parallel-connected, independently-controllable FET devices on a single fin.

2. The semiconductor chip of claim 1, further comprising a logic gate comprising the three parallel-connected, independently-controllable FET devices.

3. A semiconductor chip comprising a FinFET structure comprising:
a fin comprising:
a body area suitably doped for a body of an FET;
a first source/drain area;
a second source/drain area;
a first FET on a first vertical surface of the fin and having a first gate electrode, the first FET when turned on, providing a first current path from the first source/drain area to the second source/drain area;
a second FET on a top surface of the fin and having a second gate electrode, the second gate electrode electrically independent of the first gate electrode, the second FET when turned on, providing a second current path from the first source/drain area to the second source/drain area; and
a third FET on a second vertical surface of the fin and having a third gate electrode, the third gate electrode electrically independent from the first and second gate electrode, the third FET when turned on, providing a third current path from the first source/drain area to the second source/drain area.

4. A method for creating three parallel-connected FETs on a fin in a FinFET structure comprising:
creating a raised silicon structure (fin) on a semiconductor substrate, the raised silicon structure suitably doped for a body of an FET;
creating a first FET on a first vertical surface of the fin;
creating a second FET on a top surface of the fin, the second FET independently controllable from the first FET; and
creating a third FET on a second vertical surface of the fin, the second FET independently controllable from the first FET and the second FET.

5. The method of claim 4, the steps of creating the first, second, and third FET further comprises:
creating a first thin dielectric layer over the semiconductor substrate, a first vertical side of the fin, a top of the fin, and a second vertical side of the fin;
creating a first gate electrode layer over the semiconductor substrate, the first vertical side of the fin, the top of the fin, and the second vertical side of the fin;
etching the first thin dielectric layer and the first gate electrode layer to define where gates on the fin will be;
doping remaining portions of the fin suitably for FET source/drain areas;
creating a thick dielectric area that covers the fin and remaining portions of the thin dielectric structure and the gate electrode;
planarizing deeply enough to remove a top portion of the fin, and isolating a first portion of the first gate electrode layer from a second portion of the first gate electrode layer;
creation of a second thin dielectric layer and a second gate electrode layer;
etching the second thin dielectric layer and the second gate electrode layer so that a remaining portion of the second thin dielectric layer and the second gate electrode area cover exposed portions of the first thin dielectric layer and the first gate electrode layer, the remaining portion of the second thin dielectric layer electrically isolating the first and second portions of the first gate electrode layer from the remaining portion of the second gate electrode layer; and
providing contacts to the first portion of the first gate electrode layer, the second portion of the first gate electrode layer, and the second gate electrode layer.

6. The method of claim 4, the steps of creating the first, second, and third FET further comprises:
creating a first thin dielectric layer over the semiconductor substrate, a first vertical side of the fin, a top of the fin, and a second vertical side of the fin;
creating a first gate electrode layer over the semiconductor substrate, the first vertical side of the fin, the top of the fin, and the second vertical side of the fin;
etching the first thin dielectric layer and the first gate electrode layer to define where gates on the fin will be;
doping remaining portions of the fin suitably for FET source/drain areas;
creating a thick dielectric layer that covers the fin and remaining portions of the thin dielectric layer and the gate electrode layer;
performing a timed oxide etch deeply enough to expose a portion of the gate electrode layer and a portion of the first thin dielectric layer on a top surface of the fin;
performing a selective polysilicon etch to remove the portion of the gate electrode layer on the top surface of the fin, leaving a first portion of the first gate electrode layer and a second portion of the first gate electrode layer;
performing a selective oxide etch to remove the portion of the first thin dielectric layer on the top surface of the fin;
creating a second thin dielectric layer over the fin, covering top portions of remaining portions of the first gate electrode layers remaining on the first and second vertical surfaces of the fin;
creating a second gate electrode layer over the second thin dielectric layer;
growing additional dielectric over the thick dielectric layer and the second gate electrode layer; and
forming electrical connections to the first portion of the first gate electrode layer, the second portion of the first gate electrode layer and the second gate electrode layer.
